(19) United States
(12) Patent Application Publication
(10) Pub. No.: US 2025/0351715 A1
(43) Pub. Date: Nov. 13, 2025

(54) METHOD FOR FABRICATING TRANSISTOR ARRAY SUBSTRATE, AND METHOD FOR FABRICATING DISPLAY DEVICE

(71) Applicants: Samsung Display Co., LTD., Yongin-si (KR); Research & Business Foundation SUNGKYUNKWAN UNIVERSITY, Suwon-Si (KR)

(72) Inventors: Gung Yong YEOM, Seoul (KR); Yu Gwang JEONG, Yongin-si (KR); Da Woon JUNG, Yongin-si (KR); Dong Woo KIM, Seoul (KR); Yun Jong YEO, Yongin-si (KR); Hyun Min CHO, Yongin-si (KR); Jong Woo HONG, Goyang-si (KR)

(21) Appl. No.: 19/015,267

(22) Filed: Jan. 9, 2025

(30) Foreign Application Priority Data
May 7, 2024 (KR) 10-2024-0059796

(51) Int. Cl. H10K 71/20; H10K 59/12; H10K 59/121

(52) U.S. Cl. CPC H10K 71/233; H10K 59/1201; H10K 59/1213

(57) ABSTRACT

A method for fabricating a transistor array substrate and a method for fabricating a display device are provided. The method of fabricating the transistor array substrate includes forming on a substrate, a material layer for an oxide semiconductor layer containing IGZO, forming a photoresist pattern on the material layer for the oxide semiconductor layer, and etching the material layer for the oxide semiconductor layer using an etching gas containing a fluorinated hydrocarbon gas represented by CxHyFz, wherein x, y and z are each integers from 1 to 10.

### CROSS-REFERENCE TO RELATED APPLICATION

This application claims priority to and the benefit of Korean Patent Application No. 10-2024-0059796, filed on May 7, 2024, in the Korean Intellectual Property Office, the entire disclosure of which is incorporated herein by reference.

### BACKGROUND

### 1. Field

One or more aspects of embodiments of the present disclosure relate to a method for fabricating a transistor array substrate and a method for fabricating a display device.

### 2. Description of the Related Art

As the information-oriented society evolves, the demand for display devices continues to grow. These display devices are now being employed in a variety of electronic devices, including smart phones, digital cameras, laptop computers, navigation devices, smart televisions (TVs) and/or the like.

With the advancement (evolvement) of multimedia technology, display devices have become increasingly important. Various types (kinds) of display devices, such as liquid-crystal display (LCD) devices (displays) and organic light-emitting diode (OLED) display devices (displays) are currently in use. Among them, organic light-emitting diode (OLED) display devices (e.g., organic light-emitting display devices (displays)), in particular, utilize organic light-emitting elements that emit light when electrons and holes recombine. These organic light-emitting display devices includes a plurality of transistors that provide a (necessary or desired) driving current to the organic light-emitting elements.

Each of these transistors may include an active layer, which may include (e.g., be composed of) an oxide (e.g., oxide materials), such as an indium-gallium-zinc oxide (IGZO). The active layer containing IGZO (e.g., the IGZO active layer) boasts (has) excellent or suitable electrical properties, making high precision essential or desired. Here, high precision is essential, required, or desired because the electrical properties of the IGZO active layer directly affect the performance of the transistors. These transistors control the driving current to the organic light-emitting elements, which impacts the display's brightness, color accuracy, and/or overall image quality. Ensuring high precision in the fabrication of these active layers should ensure that the display operates reliably and produces high-quality images.

### SUMMARY

One or more aspects of embodiments of the present disclosure are directed toward a method for fabricating a transistor array substrate that may precisely etch an oxide semiconductor layer including IGZO, and a method for fabricating a display device.

It should be noted that objectives of the present disclosure are not limited to the herein-mentioned aspect; and other objectives of the present disclosure will be apparent to those skilled in the art from the following descriptions.

Additional aspects will be set forth in part in the description which follows and, in part, will be apparent from the description, or may be learned by practice of the presented embodiments of the disclosure.

According to an embodiment of the present disclosure, a method of fabricating a transistor array substrate may include forming on a substrate, a material layer, the material layer being for an oxide semiconductor layer including IGZO, forming a photoresist pattern on the material layer for the oxide semiconductor layer, and etching the material layer for the oxide semiconductor layer using an etching gas including a fluorinated hydrocarbon gas represented by CxHyFz, wherein x, y and z may each independently be an integer from 1 to 10.

In one or more embodiments, y may be greater than z.

In one or more embodiments, the fluorinated hydrocarbon gas may include at least one selected from the group consisting of C₃H₂F₆, C₃H₄F₄, and C₃H₆F₂.

In one or more embodiments, the etching gas may further include argon gas.

In one or more embodiments, a proportion (e.g., amount) of the argon gas may be (e.g., ranges) from 60% to 99% and a proportion (e.g., amount) of the fluorinated hydrocarbon gas may be (e.g., ranges) from 1% to 40% in a total sum of the fluorinated hydrocarbon gas and the argon gas. For example, an amount of the argon gas may be from 60% to 99% and an amount of the fluorinated hydrocarbon gas may be from 1% to 40% based on a total sum amount of 100% for the fluorinated hydrocarbon gas and the argon gas

In one or more embodiments, the etching of the material layer for the oxide semiconductor layer may include (e.g., be performed or is carried out with) a source power from 1,000 watt (W) to 5,000 W.

In one or more embodiments, the etching of the material layer for the oxide semiconductor layer may include (e.g., be performed or is carried out with) a bias voltage from −150 volt (V) to −500 V.

In one or more embodiments, the etching of the material layer for the oxide semiconductor layer may include (e.g., be performed or is carried out with) a ratio of a source power to a bias voltage from 8 to 30.

In one or more embodiments, the etching of the material layer for the oxide semiconductor layer may include (e.g., be performed or is carried out with) a process pressure from 1 millitorr (mTorr) to 10 mTorr.

In one or more embodiments, the etching of the material layer for the oxide semiconductor layer may include (e.g., be performed or is carried out with) a temperature of the substrate from 10° C. to 100° C.

In one or more embodiments, an etch selectivity of the etching gas to the material layer (e.g., for the oxide semiconductor layer) may be (e.g., ranges) from 1.5 to 3.

In one or more embodiments, an etch rate of the material layer (e.g., for the oxide semiconductor layer) may be (e.g., ranges) from 30 nanometer per minute (nm/min) to 60 nm/min.

In one or more embodiments, the etching of the material layer includes forming the oxide semiconductor layer and the method further includes removing the photoresist pattern after the oxide semiconductor layer is formed.

In one or more embodiments, the method further includes forming a gate electrode, a source electrode and a drain electrode on the oxide semiconductor layer.

According to an embodiment of the present disclosure, a method of fabricating a transistor array substrate may include forming on a substrate, a material layer, the material layer being for an oxide semiconductor layer including IGZO, forming a photoresist pattern on the material layer for the oxide semiconductor layer, etching the material layer for the oxide semiconductor layer using an etching gas including a fluorinated hydrocarbon gas represented by CxHyFz, wherein x, y and z may each independently be an integer from 1 to 10, forming a gate electrode, a source electrode and a drain electrode on the oxide semiconductor layer, and forming an emission material layer including an anode electrode, a light emitting layer, and a cathode electrode on the source electrode and the drain electrode.

In one or more embodiments, the fluorinated hydrocarbon gas includes at least one selected from the group consisting of C₃H₂F₆, C₃H₄F₄, and C₃H₆F₂.

In one or more embodiments, the etching gas further includes argon gas, and wherein a proportion (e.g., amount) of the argon gas may be (e.g., ranges) from 60% to 99% and a proportion (e.g., amount) of the fluorinated hydrocarbon gas may be (e.g., ranges) from 1% to 40% in a total sum of the fluorinated hydrocarbon gas and the argon gas. For example, an amount of the argon gas may be from 60% to 99% and an amount of the fluorinated hydrocarbon gas may be from 1% to 40% based on a total sum amount of 100% for the fluorinated hydrocarbon gas and the argon gas.

In one or more embodiments, the etching of the material layer for the oxide semiconductor layer may include (e.g., be performed or is carried out with) a source power from 1,000 W to 5,000 W, a bias voltage from −150 V to −500 V, and a ratio of the source power to the bias voltage from 8 to 30.

In one or more embodiments, the etching of the material layer for the oxide semiconductor layer may include (e.g., be performed or is carried out with) a process pressure from 1 millitorr (mTorr) to 10 mTorr.

In one or more embodiments, the etching of the material layer for the oxide semiconductor layer may include (e.g., be performed or is carried out with) a temperature of the substrate from 10° C. to 100° C.

According to one or more embodiments of the present disclosure, an electronic device may comprise a display device manufactured using a method for manufacturing of a display device and configured to provide an image, a processor configured to provide an image data signal to the display device, a memory configured to store a data information for operation, and a power module configured to generate power, wherein the method comprises forming on a substrate, a material layer, the material layer being for an oxide semiconductor layer including IGZO, forming a photoresist pattern on the material layer for the oxide semiconductor layer, etching the material layer for the oxide semiconductor layer using an etching gas including a fluorinated hydrocarbon gas represented by CxHyFz, wherein x, y and z may each independently be an integer from 1 to 10, forming a gate electrode, a source electrode and a drain electrode on the oxide semiconductor layer, and forming an emission material layer including an anode electrode, a light emitting layer, and a cathode electrode on the source electrode and the drain electrode.

According to one or more embodiments of the present disclosure, in an etching process (method) for forming an oxide semiconductor layer including IGZO, a high etch selectivity and/or a high etch rate may be achieved by using a fluorinated hydrocarbon (CxHyFz) gas as an etching gas. As a result, electrical characteristics of transistors may be enhanced or improved, and display quality may be enhanced or improved.

It should be noted that aspects, embodiments, and/or effects of the present disclosure are not limited to those described herein. Other aspects, embodiments, and/or effects of the present disclosure will be apparent to those skilled in the art from the following descriptions.

### BRIEF DESCRIPTION OF THE DRAWINGS

The accompanying drawings are included to provide a further understanding of the preceding and other aspects, features, and advantages of certain embodiments of the present disclosure are incorporated in and constitute a part of this specification. The drawings illustrate example embodiments that will become more apparent by describing in more detail embodiments thereof with reference to the attached drawings. In the drawings:

FIG. 1 is a plan view of a display device according to one or more embodiments of the present disclosure.

FIG. 2 is a side view of the display device of FIG. 1 when it is bent.

FIG. 3 is an equivalent circuit diagram of a pixel of a display device according to one or more embodiments of the present disclosure.

FIG. 4 is a cross-sectional view showing an example of a pixel of the display area.

FIGS. 5 to 8 are cross-sectional views showing processing steps (e.g., acts or tasks) of a method of fabricating a transistor array substrate according to one or more embodiments of the present disclosure.

FIG. 9 is a graph showing the etch selectivity and the etch rate of the IGZO layer according to Example 1.

FIG. 10 is a scanning electron microscope (SEM) image of a substrate etched using Ar gas and CH₄ gas according to Example 1.

FIG. 11 is an SEM image of a substrate etched using Ar gas and CF₄ gas according to Example 1.

FIG. 12 is a graph showing the etch selectivity and the etch rate of the IGZO layer according to Example 2.

FIG. 13 is a graph showing the etch rate of the IGZO layer according to Example 3.

FIG. 14 is a graph showing the etch selectivity of the IGZO layer according to Example 3.

FIG. 15 is an SEM image of a cross-section of the substrate according to Example 3.

FIG. 16 is an SEM image of another cross-section of the substrate according to Example 3.

FIG. 17 is an SEM image of the substrate according to Example 3 when viewed from the top.

FIG. 18 shows images in which the surface roughness of the IGZO layer and silicon oxide according to Example 3 are measured.

FIG. 19 is a graph showing results measured by a quartz crystal microbalance (QCM) equipment during the process of cleaning after etching the IGZO layer according to Example 3.

FIG. 20 is a block diagram of an electronic device according to one or more embodiments of the present disclosure.

FIG. 21 is a schematic diagram of electronic devices according to one or more embodiments of the present disclosure.

### DETAILED DESCRIPTION

Reference will now be made in more detail to one or more embodiments, examples of which are illustrated with reference to the accompanying drawings, and in which example embodiments of the present disclosure are shown. The present disclosure may, however, be embodied in different forms and should not be construed as limited to one or more embodiments set forth herein. Rather, these embodiments are provided so that this disclosure will be thorough and complete, and will fully convey the scope of the present disclosure to those skilled in the art.

It will also be understood that if (e.g., when) a component such as a layer, substrate, and/or the like is referred to as being “on” or “connected to” another component, it may be directly on the other layer or substrate, or intervening layers or substrates may also be present. The same reference numbers indicate the same components throughout the specification, and thus redundant descriptions thereof will not be provided. Sizes of elements in the drawings may be exaggerated for convenience of explanation. In other words, because sizes and thicknesses of components in the drawings are arbitrarily illustrated for convenience of explanation, the following embodiments are not limited thereto.

It will be understood that, although the terms “first,” “second,” and/or the like may be used herein to describe one or more suitable elements, these elements should not be limited by these terms. These terms are only used to distinguish one element from another element. For instance, a first element discussed herein could be termed a second element without departing from the teachings of the present disclosure. Similarly, the second element could also be termed the first element.

Each of the features of the one or more suitable embodiments of the present disclosure may be combined or combined with each other, in part or in whole, and technically one or more suitable interlocking and driving are possible. Each embodiment may be implemented independently of each other or may be implemented together in an association.

An expression utilized in the singular forms such as “a,” “an,” and “the” are intended to encompass the expression of the plural forms as well, unless it has a clearly different meaning in the context.

Unless otherwise defined, all chemical names, technical and scientific terms, and terms defined in common dictionaries should be interpreted as having meanings consistent with the context of the related art, and should not be interpreted in an ideal or overly formal sense.

As used herein, the term “and/or” includes any and all combinations of one or more of the associated listed items. Expressions such as “at least one of,” “one of,” “selected from,” and “selected from among,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

Because the disclosure may have diverse modified embodiments, the embodiments are illustrated in the drawings and are described in the detailed description. An aspect and a characteristic of the disclosure, and a method of accomplishing these will be apparent if (e.g., when) referring to one or more embodiments described with reference to the drawings. The disclosure may, however, be embodied in many different forms and should not be construed as limited to the embodiments set forth herein.

It will be further understood that the terms “comprises,” “comprising,” “comprise,” “has,” “have,” “having,” “include,” “includes,” and/or “including,” as utilized herein specify the presence of stated features or elements, but do not preclude the presence or addition of one or more other features or elements.

As used herein, the terms “use,” “using,” and “used” may be considered synonymous with the terms “utilize,” “utilizing,” and “utilized,” respectively.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

In this context, “consisting essentially of” indicates that any additional components will not materially affect the chemical, physical, optical or electrical properties of the semiconductor film.

Further, in this specification, the phrase “on a plane,” or “plan view,” indicates viewing a target portion from the top, and the phrase “on a cross-section” indicates viewing a cross-section formed by vertically cutting a target portion from the side.

Hereinafter, embodiments of the present disclosure will be described with reference to the accompanying drawings.

### Display Device

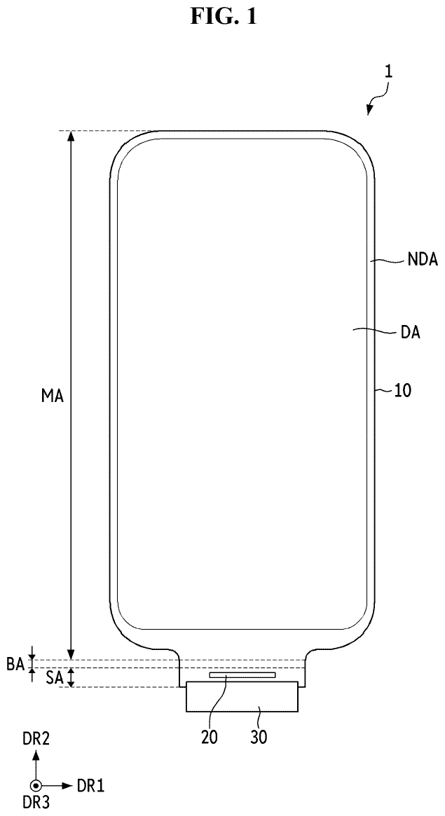

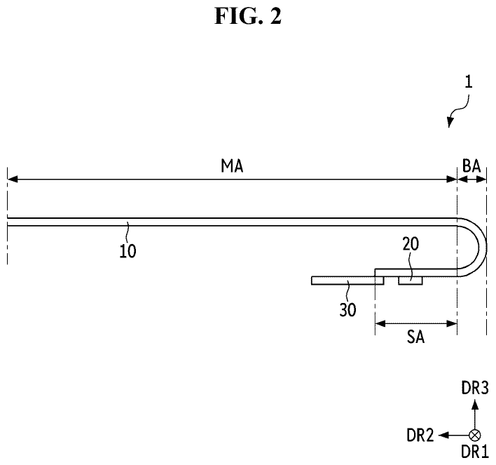

FIG. 1 is a plan view of a display device according to one or more embodiments of the present disclosure. FIG. 2 is a side view of the display device of FIG. 1 when it is bent. FIG. 2 shows a side shape of the display device when it is bent in a thickness direction.

A display device 1 shown in FIG. 1 displays moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device a ultra mobile PC (UMPC), and/or the like, as well as the display screen of one or more suitable products such as a television, a notebook, a monitor, a billboard a component of the Internet of Things, and/or the like.

According to one or more embodiments of the present disclosure, the display device 1 may have a substantially rectangular shape when viewed from the top. The display device 1 may have a rectangular shape with corners at the right angle when viewed from the top. It is, however, to be understood that the present disclosure is not limited thereto. For example, the display device 1 may have a rectangular shape with rounded corners when viewed from the top.

In the drawings, a first direction DR1 denotes a horizontal direction of the display device 1 and a second direction DR2 denotes a vertical direction of the display device 1 when viewed from the top. In some embodiments, the third direction DR3 may refer to a thickness direction of the display device 1. The first direction DR1 is normal (e.g., perpendicular) to the second direction DR2. The third direction the third direction DR3 is orthogonal to the plane in which the first direction DR1 and the second direction DR2 lie and is normal (e.g., perpendicular) to the first direction DR1 as well as the second direction DR2. It should be understood that the directions referred to in one or more embodiments are relative directions, and one or more embodiments are not limited to the directions mentioned.

As used herein, the terms “top”, “upper surface” and “upper side” in the third direction DR3 refer to the display side of a display panel 10, whereas the terms “bottom”, “lower surface” and “lower side” refer to the opposite side of a display panel 10, unless stated otherwise.

Referring to FIGS. 1 and 2, the display device 1 may include the display panel 10. The display panel 10 may be a flexible substrate including a flexible polymer material such as polyimide. Accordingly, the display panel 10 may be curved, bent, folded, rolled, and/or the like.

The display panel 10 may be an organic light-emitting display panel. In the following description, the organic light-emitting display panel is employed as the display panel 10. It is, however, to be understood that other types (kinds) of display panels may be employed as the display panel 10, such as a liquid-crystal display (LCD) panel, a quantum-dot organic light-emitting display (QD-OLED) panel, a quantum-dot liquid-crystal display (QD-LCD) panel, a quantum-nano light-emitting display (Nano NED) panel, a micro LED panel, and/or the like.

The display panel 10 may include a display area DA where images are displayed, and a non-display area NDA where no image is displayed. The display panel 10 may include the display area DA and the non-display area NDA when viewed from the top. The non-display area NDA may be around (e.g., surround) the display area DA. The non-display area NDA may form a bezel.

The display area DA may have a rectangular shape having corners at the right angle or rounded corners when viewed from the top. The display area DA may include shorter sides and longer sides. The shorter sides of the display area DA may be extended in a first direction DR1. The longer sides of the display area DA may be extended in a second direction DR2. It is, however, to be understood that the present disclosure is not limited thereto. The shape of the display area DA is not limited to a rectangle, and it may have other shapes such as a circle, an ellipse, and/or the like.

The display area DA may include a plurality of pixels. The pixels may be arranged in a matrix. Each of the pixels may include a light emitting layer and a circuit layer for selecting or controlling the amount of light emitted from the light emitting layer. The circuit layer may include lines, electrodes and at least one transistor. The light emitting layer may include an organic light-emitting material. The light emitting layer may be encapsulated by an encapsulation layer. The configuration of the pixels will be described in more detail elsewhere herein.

The non-display area NDA may be arranged adjacent to the two shorter sides and the two longer sides of the display area DA. In such case, the display area NA may be around (e.g., surround) all of the sides of the display area DA and may form the edges of the display area DA. It is, however, to be understood that the present disclosure is not limited thereto. The non-display area NDA may be arranged adjacent only to the two shorter sides or only to the two longer sides of the display area DA.

The display panel 10 may include a main area MA and a bending area BA connected to one side of the main area MA in the second direction DR2. The display panel 10 may further include a subsidiary area SA connected to one side of the bending area BA in the second direction DR2 and overlapping the main area MA when it is bent in the thickness direction.

The display area DA may be located in the main area MA. The non-display area NDA may be located at the peripheral edge of the display area DA in the main area MA.

The main area MA may have a shape substantially similar to the outer shape of the display device 1 when viewed from the top. The main area MA may be a flat area located in one plane. It is, however, to be understood that the present disclosure is not limited thereto. At least one of (e.g., selected from among) the edges of the main area MA except for the edge (side) connected to the bending area BA may be bent to form a curved surface or may be bent at a right angle.

When at least one of the edges of the main area MA except for the edge (side) connected to the bending area BA is curved or bent, the display area DA may also be arranged at the edge. It is, however, to be understood that the present disclosure is not limited thereto. The non-display area NDA that does not display image may be arranged on the curved or bent edge, or the display area DA and the non-display area NDA may be arranged together.

The non-display area NDA of the main area MA may be extended from the outer border of the display area DA to the edge of the display panel 10. In the non-display area NDA of the main area MA, signal lines for applying signals to the display area DA or driving circuits may be arranged.

The bending area BA may be connected through one shorter side of the main area MA. The width of the bending area BA (the width in the first direction DR1) may be smaller than the width of the main area MA (the width of the shorter side). The portions where the main area MR meets the bending area BR may be cut in an L-shape in order to reduce the bezel width.

In the bending area BA, the display panel 10 may be bent with a curvature toward the opposite side of the display surface. As the display panel 10 is bent at the bending area BA, the surface of the display panel 10 may be reversed. For example, the surface of the display device 10 opposite to (e.g., facing) upward may be bent such that it faces outward at the bending area BA and then faces downward.

The subsidiary area SA is extended from the bending area BA. The subsidiary area SA may be extended in a direction parallel to the main area MA from the end of the bending region. The subsidiary area SA may overlap with the main area MA in the thickness direction of the display panel 10. The subsidiary area SA may overlap with the non-display area NDA at the edge of the main area MA and may also overlap with the display area DA of the main area MA. The width of the subsidiary area SA may be, but is not limited to being, equal to the width of the bending area BA.

A pad area may be located on the subsidiary area SA of the display panel 10. An external device may be mounted on (or attached to) the pad area. Examples of the external device include a driving chip 20, a driving board 30 implemented as a flexible printed circuit board or a rigid printed circuit board. Other line connection films, connectors, and/or the like, may be mounted on the pad area as well. More than one external devices may be mounted on the subsidiary area SA. For example, as shown in FIGS. 1 and 2, the driving chip 20 may be arranged in the subsidiary area SA of the display panel 10, and the driving board 30 may be attached to an end of the subsidiary area SA. In such case, the display device 10 may include a pad area connected to the driving chip 20, as well as a pad area connected to the driving board 30. According to one or more embodiments, a driving chip may be mounted on a film, and the film may be attached to the subsidiary area SA of the display panel 10.

The driving chip (e.g., driving circuit(s)) 20 is mounted on the surface of the display panel 10 which is the display surface. As the bending area BA is bent and accordingly the surface is reversed as described herein, the driving chip 20 may be mounted on the surface of the display panel 10 opposite to (e.g., facing) downward in the thickness direction, such that the upper surface of the driving chip 20 may face downward.

The driver chip 20 may be attached on the display panel 10 by an anisotropic conductive film or on the display panel 10 by ultrasonic bonding. The width of the driving chip 20 may be less than the width of the display panel 10 in the horizontal direction. The driving chip 20 may be arranged at the center of the subsidiary area SA in the horizontal direction (the first direction DR1), and the left and right edges of the driving chip 20 may be spaced and/or apart (e.g., spaced apart or separated) from the left and right edges of the subsidiary area SA, respectively.

The driver chip 20 may include an integrated circuit for driving the display panel 10. According to one or more embodiments, the integrated circuit may be, but is not limited to, a data driving integrated circuit that generates and provides data signals. The driving chip 20 is connected to a wire pad arranged in the pad area of the display panel 10 to provide data signals toward the wire pad. Lines connected to the wire pad may be extended toward the pixels to apply a data signal and/or the like to the pixels.

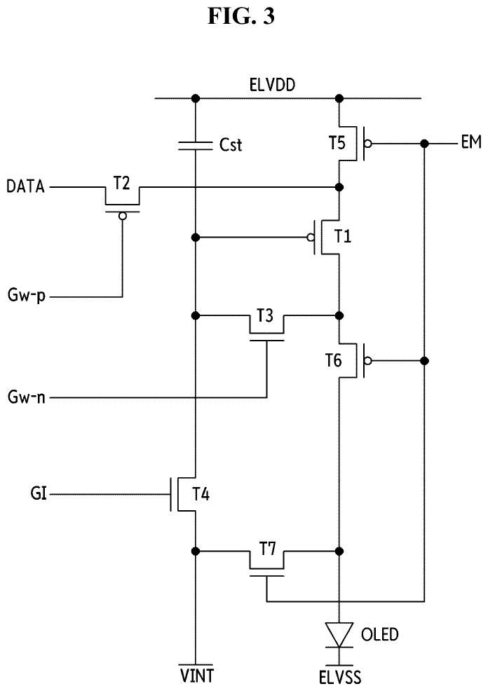

FIG. 3 is an equivalent circuit diagram of a pixel of a display device according to one or more embodiments of the present disclosure.

Referring to FIG. 3, the circuit of a pixel of the organic light-emitting display device includes an organic light-emitting diode OLED, a plurality of transistors T1 to T7, and a capacitor Cst. To the circuit of the pixel, a data signal DATA, a first scan signal GW-p, a second scan signal Gw-n, a third scan signal GI, an emission control signal EM, a first supply voltage ELVDD, a second supply voltage ELVSS, and an initialization voltage VINT are applied.

The organic light-emitting diode OLED includes an anode electrode and a cathode electrode. The capacitor Cst includes a first electrode and a second electrode. The plurality of transistors may include first to seventh transistors T1 to T7.

Each of the transistors T1 to T7 includes a gate electrode, a first source/drain electrode and a second source/drain electrode. One of the first source/drain electrode and the second source/drain electrode of each of the transistors T1 to T7 works as a source electrode and the other works as a drain electrode.

Each of the transistors T1 to T7 may be a thin-film transistor. Each of the transistors T1 to T7 may be either a PMOS transistor or an NMOS transistor. According to the embodiment, the first transistor T1 as a driving transistor, the second transistor T2 as a data transfer transistor, the fifth transistor T5 as a first emission control transistor, and the sixth transistor T6 as a second emission control transistor are PMOS transistors. In contrast, the third transistor T3 as a compensating transistor, the fourth transistor T4 as a first initializing transistor and the seventh transistor T7 as a second initializing transistor are NMOS transistors. The PMOS transistors and the NMOS transistors have different characteristics. The third transistor T3, the fourth transistor T4 and the seventh transistor T7 are implemented as NMOS transistors having a relatively good or suitable turn-off characteristic, so that leakage of the driving current during the emission period of the organic light-emitting diode OLED may be reduced.

Hereinafter, each of the elements will be described in more detail.

The gate electrode of the first transistor T1 is connected to a first electrode of a capacitor Cst. The first source electrode of the first transistor T1 is connected to the first supply voltage ELVDD via the fifth transistor T5. The first drain electrode of the first transistor T1 is connected to the anode electrode of the organic light-emitting diode OLED via the sixth transistor T6. The first transistor T1 receives the data signal DATA according to the switching operation of the second transistor T2 to supply the driving current to the organic light-emitting diode OLED.

The gate electrode of the second transistor T2 is connected to the first scan signal GW-p terminal. The first source electrode of the second transistor T2 is connected to the data signal DATA terminal. The first drain electrode of the second transistor T2 is connected to the first source electrode of the first transistor T1 and is connected to the first supply voltage ELVDD terminal via the fifth transistor T5. The second transistor T2 is turned on according to the first scan signal GW-p and performs a switching operation to transfer the data signal DATA to the first source electrode of the first transistor T1.

The gate electrode of the third transistor T3 is connected to the second scan signal Gw-n terminal. The first source electrode of the third transistor T3 is connected to the first drain electrode of the first transistor T1 and is connected to the anode electrode of the organic light-emitting diode OLED via the sixth transistor T6. The first drain electrode of the third transistor T3 is connected to the first electrode of the capacitor Cst, the first source electrode of the fourth transistor T4 and the gate electrode of the first transistor T1. The third transistor T3 is turned on in response to the second scan signal Gn-p to connect the gate electrode with the first drain electrode of the first transistor T1, to diode-connect the first transistor T1. Accordingly, a voltage difference equal to the threshold voltage of the first transistor T1 is generated between the first source electrode and the gate electrode of the first transistor T1. Deviations in the threshold voltage of the first transistor T1 may be compensated by supplying the data signal DATA that compensates for the threshold voltage to the gate electrode of the first transistor T1.

The gate electrode of the fourth transistor T4 is connected to the third scan signal (GI) terminal. The first drain electrode of the fourth transistor T4 is connected to the initialization voltage (VINT) terminal. The first source electrode of the fourth transistor T4 is connected to the first electrode of the capacitor Cst, the first drain electrode of the third transistor T3 and the gate electrode of the first transistor T1. The fourth transistor T4 is turned on in response to the third scan signal GI to transfer the initialization voltage VINT to the gate electrode of the first transistor T1, to initialize the voltage at the gate electrode of the first transistor T1.

The gate electrode of the fifth transistor T5 is connected to the emission control signal EM terminal. The first source electrode of the fifth transistor T5 is connected to the first supply voltage ELVDD terminal. The first drain electrode of the fifth transistor T5 is connected to the first source electrode of the first transistor T1 and the first drain electrode of the second transistor T2.

The gate electrode of the sixth transistor T6 is connected to the emission control signal EM terminal. The first source electrode of the sixth transistor T6 is connected to the first drain electrode of the first transistor T1 and the first source electrode of the third transistor T3. The first drain electrode of the sixth transistor T6 is connected to the anode electrode of the organic light-emitting diode OLED.

The fifth transistor T5 and the sixth transistor T6 are concurrently (e.g., simultaneously) turned on in response to the emission control signal EM so that the driving current flows through the organic light-emitting diode OLED.

The gate electrode of the seventh transistor T7 is connected to the emission control signal EM terminal. The first source electrode of the seventh transistor T7 is connected to the anode electrode of the organic light-emitting diode OLED. The first drain electrode of the seventh transistor T7 is connected to the initialization voltage VINT terminal. The seventh transistor T7 is turned on in response to the emission control signal EM to initialize the anode electrode of the organic light-emitting diode OLED.

Although the seventh transistor T7 receives the same emission control signal EM as the fifth transistor T5 and the sixth transistor T6, they may be turned on at different timings because the seventh transistor T7 is an NMOS transistor while the fifth transistor T5 and the sixth transistor T6 are PMOS transistors. That is to say, if (e.g., when) the emission control signal EM is at a high level, the seventh transistor T7 is turned on while the fifth transistor T5 and the sixth transistor T6 are turned off. When the emission control signal EM is at a low level, the seventh transistor T7 is turned off while the fifth transistor T5 and the sixth transistor T6 are turned on. Accordingly, the initialization operation by the seventh transistor T7 may be not performed at the time of emission if (e.g., when) the fifth transistor T5 and the sixth transistor T6 are turned on, while the initialization operation by the seventh transistor T7 may be performed at a non-emission time if (e.g., when) the fifth transistor T5 and the sixth transistor T6 are turned off.

Although the emission control signal EM is applied to the gate electrode of the seventh transistor T7 in this embodiment of the present disclosure, the pixel circuit may be configured such that the third scan signal GI may be applied to the gate electrode of the seventh transistor T7 or a separate scan signal may be received in other implementations.

The second electrode of the capacitor Cst is connected to the first supply voltage ELVDD terminal. The first electrode of the capacitor Cst is connected to the gate electrode of the first transistor T1, the first drain electrode of the third transistor T3 and the first source electrode of the fourth transistor T4. The cathode electrode of the organic light-emitting diode OLED is connected to the second supply voltage ELVSS terminal. The organic light-emitting diode OLED receives the driving current from the first transistor T1 and emits light to display images.

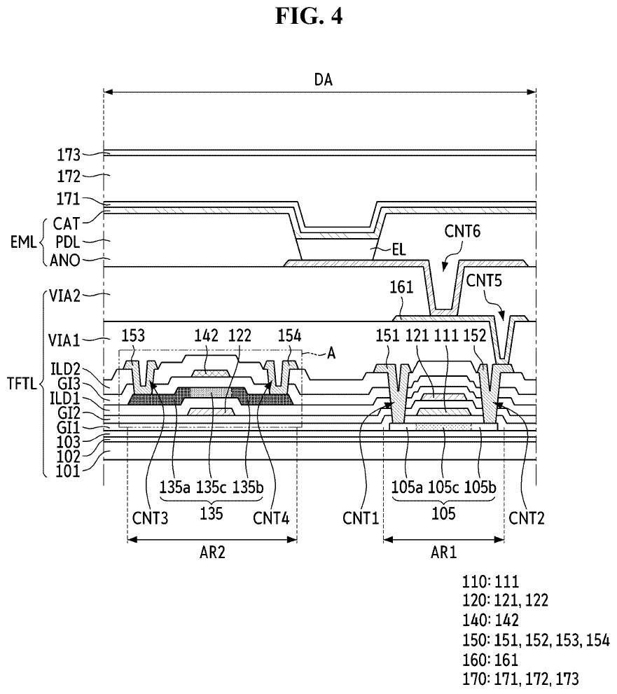

Hereinafter, the cross-sectional structure of the display panel 10 will be described in more detail with reference to FIG. 4. FIG. 4 shows an example of the cross-sectional structure of a pixel in the display area DA of the display panel 10.

FIG. 4 is a cross-sectional view showing an example of a pixel of the display area.

Referring to FIG. 4, the display area DA of the display panel 10 will be described.

The display area DA may include a silicon transistor area AR1 in which a non-oxide inorganic semiconductor transistor including polycrystalline silicon as a channel (hereinafter referred to as a silicon transistor) is arranged, and an oxide transistor area AR2 in which an oxide semiconductor transistor including an oxide semiconductor as a channel (hereinafter referred to as an oxide transistor) is arranged.

The silicon transistor arranged in the silicon transistor area AR1 may be a PMOS transistor. FIG. 4 shows the first transistor T1, which is a driving transistor, as an example of a silicon transistor. The oxide transistor arranged in the oxide transistor area AR2 may be an NMOS transistor. FIG. 4 shows the third transistor T3, which is a compensation transistor, as an example of the oxide transistor.

The second transistor T2, the fifth transistor T5 and the sixth transistor T6 may be arranged in the silicon transistor area AR1 and are other silicon transistors.

The second transistor T2, the fifth transistor T5 and the sixth transistor T6 may have a stacked structure substantially identical to that of the first transistor T1. The fourth transistor T4 and the seventh transistor T7 may be arranged in the oxide transistor region AR2 and are other oxide transistors. The fourth transistor T4 and the seventh transistor T7 may have a stacked structure substantially identical to that of the third transistor T3. The silicon transistor and the oxide transistor will be described in more detail elsewhere herein.

The display panel 10 may include a transistor array substrate TFTL and an emission device layer EML. The transistor array substrate TFTL may include a substrate 101, a barrier layer 102, a buffer layer 103, a silicon semiconductor layer 105, a first gate insulator GI1, a first conductive layer 110, a second gate insulator GI2, a second conductive layer 120, a first interlayer dielectric film ILD1, an oxide semiconductor layer 135, a third gate insulator GI3, a third conductive layer 140, a second interlayer dielectric film ILD2, a fourth conductive layer 150, a first via layer VIA1, a fifth conductive layer 160, and a second via layer VIA2. The emission device layer EML may include an anode electrode ANO, a pixel-defining layer PDL, a light emitting layer EL, and a cathode electrode CAT. Each of the layers described herein may be made up of a single film, or a stack of multiple films. Other layers may be further arranged between the layers.

The substrate 101 may support a variety of layers arranged thereon. The substrate 101 may be made of, for example, an insulating material such as a polymer resin. Examples of the polymer material may include polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP) and/or a (e.g., any suitable) combination thereof. The substrate 101 may include a metal material.

The substrate 101 may be a flexible substrate that may be bent, folded, rolled, and/or the like. An example of the material of the flexible substrate may be, but is not limited to, polyimide (PI).

A transparent substrate may be used if (e.g., when) the organic light-emitting display device is of a bottom-emission or both-sided emission type (kind). When the organic light-emitting display device is of a top-emission type (kind), a semitransparent or opaque substrate as well as a transparent substrate may be employed.

The barrier layer 102 may be arranged on the substrate 101. The barrier layer 102 may prevent or reduce impurity ions from diffusing, may prevent or reduce permeation of moisture and/or outside air, and may provide a flat surface. The barrier layer 102 may include silicon nitride, silicon oxide, silicon oxynitride, and/or the like. The barrier layer 102 may be excluded (e.g., eliminated) depending on the type (kind) of the substrate 101, process conditions, and/or the like.

The buffer layer 103 may be arranged on the barrier layer 102. The buffer layer 103 may be made of a material including at least one of silicon nitride, silicon oxide and/or silicon oxynitride. The buffer layer 103 may be excluded (e.g., eliminated) depending on the type (kind) of the substrate 101, process conditions, and/or the like.

The silicon semiconductor layer 105 may be arranged on the buffer layer 103. The silicon semiconductor layer 105 may be arranged in the silicon transistor area AR1.

The silicon semiconductor layer 105 may include a non-oxide semiconductor. For example, the silicon semiconductor layer 105 may be made of polycrystalline silicon, monocrystalline silicon, amorphous silicon, and/or the like. When the silicon semiconductor layer 105 is made of polycrystalline silicon, the polycrystalline silicon may be formed by crystallizing amorphous silicon using techniques such as rapid thermal annealing (RTA), solid phase crystallization (SPC), excimer laser annealing (ELA), metal induced crystallization (MIC), metal induced lateral crystallization (MILC), sequential lateral solidification (SLS), and/or the like.

The silicon semiconductor layer 105 may include a channel region 105c overlapping with a first gate electrode 111 thereabove in the thickness direction, and a first source region 105a and a second source region 105b of the silicon semiconductor layer 105 located on one side and the other side of the channel region 105c, respectively. The first source region 105a and first drain region 105b of the silicon semiconductor layer 105 contain a large number of carrier ions, and thus may have greater conductivity and lower electrical resistance than the channel region 105c.

The silicon semiconductor layer 105 may include the semiconductor layers (or active layers) of the first transistor T1, the second transistor T2, the fifth transistor T5 and the sixth transistor T6, and may form the channels of the transistors. For example, the silicon semiconductor layer 105 may include a channel region, a first source region and a first drain region of each of the first transistor T1, the second transistor T2, the fifth transistor T5 and the sixth transistor T6.

The first gate insulator GI1 may be arranged on the silicon semiconductor layer 105. The first gate insulator GI1 may cover not only the upper surface of the silicon semiconductor layer 105 excluding where the contact holes CNT1 and CNT2 are formed, but also the side surfaces of the silicon semiconductor layer 105. The first gate insulator GI1 may be arranged generally over the entire surface of the substrate 101.

The first gate insulator GI1 may include a silicon compound, a metal oxide, and/or the like. For example, the first gate insulating film GI1 may include silicon oxide, silicon nitride, silicon oxynitride, aluminum oxide, tantalum oxide, hafnium oxide, zirconium oxide, titanium oxide, and/or the like. They may be used alone or in (e.g., any suitable) combinations.

The first conductive layer 110 may be arranged on the first gate insulator GI1. The first conductive layer 110 may include at least one metal selected from the group consisting of: molybdenum (Mo), aluminum (AI), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu).

The first conductive layer 110 is a gate conductive layer and may include the first gate electrode 111 arranged in the silicon transistor area AR1. The first gate electrode 111 may be a gate electrode of a silicon transistor. The first gate electrode 111 may be connected to the first electrode of the capacitor Cst. The first electrode of the capacitor Cst may be formed of the first gate electrode 111 itself, or may be formed of a portion extended from the first gate electrode 111. For example, a portion of the pattern of the integrated first conductive layer 111 may overlap the semiconductor pattern 105 to work as the first gate electrode 111 at that position, while another portion of the pattern may not overlap the semiconductor pattern 105 and work as the first electrode of the capacitor Cst overlapping the second electrode 151 of the capacitor Cst above it.

The second gate insulator GI2 may be arranged on the first conductive layer 110. The second gate insulator GI2 may cover not only the upper surface of the first gate electrode 111 excluding where the contact holes CNT1 and CNT2 are formed, but also the side surfaces of the first gate electrode 111. The second gate insulator GI2 may be arranged generally over the entire surface of the first gate insulator GI1.

The second gate insulator GI2 may include a silicon compound, a metal oxide, and/or the like. For example, the first gate insulating film GI1 may include silicon oxide, silicon nitride, silicon oxynitride, aluminum oxide, tantalum oxide, hafnium oxide, zirconium oxide, titanium oxide, and/or the like. They may be used alone or in (e.g., any suitable) combinations.

The second conductive layer 120 may be arranged on the second gate insulator GI2. The second conductive layer 120 may include at least one metal selected from the group consisting of: molybdenum (Mo), aluminum (AI), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu).

The second conductive layer 120 is a capacitor conductive layer and may include a second electrode 121 of the capacitor Cst arranged in the silicon transistor area AR1 and a bottom light-blocking pattern 122. The second electrode 121 of the capacitor Cst may face the first electrode of the capacitor Cst connected to the underlying first gate electrode 111 with the second gate insulator GI2 therebetween to form the capacitor Cst.

The bottom light-blocking pattern 122 may prevent or reduce light incident from below the display panel 10 from entering the oxide semiconductor layer 135 located thereabove. The bottom light-blocking pattern 122 may overlap with at least the channel region 135c of the oxide semiconductor layer 135 and may cover at least the channel region 135c of the oxide semiconductor layer 135. It should be understood, however, that one or more embodiments of the present disclosure are not limited thereto. The bottom light-blocking pattern 122 may overlap with the entire area of the oxide semiconductor layer 135.

In one or more embodiments, the bottom light-blocking pattern 122 may be used as another gate electrode of the oxide transistor. In this instance, the bottom light-blocking pattern 122 may be electrically connected to at least one of the second gate electrode 142, the first source electrode 153, and/or the first drain electrode 154 of the transistor arranged in the oxide semiconductor area AR2.

The first interlayer dielectric film ILD1 may be arranged on the second conductive layer 120. The first interlayer dielectric film ILD1 may include a silicon compound, a metal oxide, and/or the like. For example, the first interlayer dielectric film ILD1 may include silicon oxide, silicon nitride, silicon oxynitride, aluminum oxide, tantalum oxide, hafnium oxide, zirconium oxide, titanium oxide, and/or the like. They may be used alone or in (e.g., any suitable) combinations.

The oxide semiconductor layer 135 may be arranged on the first interlayer dielectric film ILD1. The oxide semiconductor layer 135 may be arranged in the oxide transistor area AR2. The oxide semiconductor layer 135 may include an oxide semiconductor. The oxide may include one or more oxides selected from among zinc (Zn), indium (In), gallium (Ga), tin (Sn) cadmium (Cd), germanium (Ge) hafnium (Hf), and/or a (e.g., any suitable) combination thereof. The oxide may include at least one of indium-gallium-zinc oxide (IGZO), zinc-tin oxide (ZTO), indium-tin oxide (IZO), and/or the like.

The oxide semiconductor layer 135 may include a channel region 135c overlapping with a third gate electrode 142 thereabove in the thickness direction, and a first source region 135a and a second source region 135b of the oxide semiconductor layer 135 located on one side and the other side of the channel region 105c, respectively. The first source region 135a and first drain region 135b of the oxide semiconductor layer 135 are made conductive, and thus may have greater conductivity and lower electrical resistance than the channel region 105c.

The oxide semiconductor layer 135 may include the semiconductor layers of the third transistor T3, the fourth transistor T4 and the seventh transistor T7 described herein, which may form the channels of the respective transistors. For example, the oxide semiconductor layer 135 may include a channel region, a first source region and a first drain region of each of the third transistor T3, the fourth transistor T4, and the seventh transistor T7.

The third gate insulator GI3 may be arranged on the oxide semiconductor layer 135. The third gate insulator GI3 may cover not only the upper surface of the oxide semiconductor layer 135 but also the side surfaces of the oxide semiconductor layer 135. The third gate insulator GI3 may be arranged generally over the entire surface of the first interlayer dielectric film ILD1.

The third gate insulator GI3 may include a silicon compound, a metal oxide, and/or the like. For example, the third gate insulator GI3 may include silicon oxide, silicon nitride, silicon oxynitride, aluminum oxide, tantalum oxide, hafnium oxide, zirconium oxide, titanium oxide, and/or the like. They may be used alone or in (e.g., any suitable) combinations.

The third conductive layer 140 may be arranged on the third gate insulator GI3. The third conductive layer 140 is a gate conductive layer and may include the third gate electrode 142 arranged in the oxide transistor area AR2. The third conductive layer 140 may include at least one metal selected from the group consisting of: molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu).

The second interlayer dielectric film ILD2 may be arranged on the third conductive layer 140. The second interlayer dielectric film ILD2 may include a silicon compound, a metal oxide, and/or the like. For example, the second interlayer dielectric film ILD2 may include silicon oxide, silicon nitride, silicon oxynitride, aluminum oxide, tantalum oxide, hafnium oxide, zirconium oxide, titanium oxide, and/or the like. They may be used alone or in (e.g., any suitable) combinations.

The fourth conductive layer 150 may be arranged on the second interlayer dielectric film ILD2. The fourth conductive layer 150 may include at least one metal selected from the group consisting of: aluminum (AI), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu).

The fourth conductive layer 150 is a data conductive layer and may include a first source electrode 151 and a first drain electrode 152 of the transistor arranged in the silicon transistor area AR1, and a first source electrode 153 and a first drain electrode 154 of the transistor arranged in the oxide transistor region AR2.

In the transistor arranged in the silicon transistor area AR1, the first source electrode 151 may be connected to the first source/drain region 105a of the silicon semiconductor layer 105 through the contact hole CNT1 that penetrates the second interlayer dielectric film ILD2, the third gate insulator GI3, the first interlayer dielectric film ILD1, the second gate insulator GI2 and the first gate insulator GI1 to expose the first source region 105a of the silicon semiconductor layer 105. The first drain electrode 152 may be connected to the first drain region 105b of the silicon semiconductor layer 105 through the contact hole CNT2 that penetrates the second interlayer dielectric film ILD2, the second gate insulator GI2 and the first gate insulator GI1 to expose the first drain region 105b of the silicon semiconductor layer 105.

The first source electrode 153 and the first drain electrode 154 of the transistor arranged in the oxide semiconductor area AR2 may be connected to the oxide semiconductor layer 135. For example, the first source electrode 153 of the transistor arranged in the oxide semiconductor area AR2 may be in contact with the first source region 135a of the oxide semiconductor layer 135 through a contact hole CNT3 that penetrates the second interlayer dielectric film ILD2 and the third gate insulator GI3 to expose the first source region 135a of the oxide semiconductor layer 135. The first drain electrode 154 of the transistor arranged in the oxide semiconductor area AR2 may be in contact with the first drain region 135b of the oxide semiconductor layer 135 through a contact hole CNT4 that penetrates the second interlayer dielectric film ILD2 and the third gate insulator GI3 to expose the first drain region 135b of the oxide semiconductor layer 135.

The first via layer VIA1 may be arranged on the fourth conductive layer 150. The first via layer VIA1 may include an inorganic insulating material or an organic insulating material such as polyacrylate resin, epoxy resin, phenolic resin, polyamide resin, polyimide resin, unsaturated polyesters resin, poly phenylene ether resin, poly phenylene sulfide resin, benzocyclobutene (BCB), and/or the like.

The via layer VIA1 may be arranged over the second interlayer dielectric film ILD2 to completely cover the upper surface of the second interlayer dielectric film ILD2. When the via layer VIA1 is formed as an organic film, it may have a flat upper surface despite the level differences thereunder.

The fifth conductive layer 160 may be arranged on the first via layer VIA1. The fifth conductive layer 160 may include at least one metal selected from the group consisting of: molybdenum (Mo), aluminum (AI), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu).

The fifth conductive layer 160 may include an anode connection electrode 161. A contact hole CNT5 exposing the first drain electrode 152 of the transistor arranged in the silicon semiconductor region AR1 may be located in the first via layer VIA1, and the anode connection electrode 161 may be connected to the first drain electrode 152 through the contact hole CNT5.

The second via layer VIA2 may be arranged over the anode connection electrode 161. The second via layer VIA2 may include an inorganic insulating material or an organic insulating material such as polyacrylate resin, epoxy resin, phenolic resin, polyamide resin, polyimide resin, unsaturated polyesters resin, poly phenylene ether resin, poly phenylene sulfide resin, benzocyclobutene (BCB), and/or the like.

An anode electrode ANO may be arranged on the second via layer VIA2. The anode electrode ANO may be a pixel electrode that is separately arranged in each of the pixels. The anode electrode ANO may be electrically connected to the anode connection electrode 161 through a contact hole CNT6 that penetrates the second via layer VIA2 to expose a portion of the anode connection electrode 161.

The anode electrode ANO may have, but is not limited to, a stack structure of a material layer having a high work function such as indium-tin-oxide (ITO), indium-zinc-oxide (IZO), zinc oxide (ZnO), indium oxide, (In₂O₃), and/or the like, and a reflective material layer such as silver (Ag), magnesium (Mg), aluminum (AI), platinum (Pt), lead (Pb), palladium (Pd), gold (Au), nickel (Ni), neodymium (Nd), iridium (Ir), chromium (Cr), lithium (Li), calcium (Ca) and/or a (e.g., any suitable) mixture thereof. A layer having a higher work function may be arranged above a reflective material layer so that it is arranged closer to the light emitting layer EL. The anode electrode ANO may have, but is not limited to, a multilayer structure of ITO/Mg, ITO/MgF, ITO/Ag, ITO/Ag/ITO, and/or the like.

The pixel-defining layer PDL may be arranged on the anode electrode ANO. The pixel-defining film PDL may include an opening exposing a portion of the anode electrode ANO. The pixel-defining layer PDL may include an organic insulating material or an inorganic insulating material. For example, the pixel-defining layer PDL may include at least one of: a polyimide resin, an acrylic resin, a silicon compound, a polyacrylic resin, and/or the like.

The light emitting layer EL may be arranged on the anode electrode ANO exposed by the pixel-defining layer PDL. The light emitting layer EL may include an organic material layer. The organic material layer of the emission layer may include an organic emission layer and may further include a hole injecting/transporting layer and/or an electron injecting/transporting layer.

The cathode electrode CAT may be arranged on the light emitting layer EL. The cathode electrode CAT may be a common electrode arranged across the pixels. The cathode electrode CAT may include a material layer having a small work function such as Li, Ca, LiF/Ca, LiF/Al, Al, Mg, Ag, Pt, Pd, Ni, Au, Nd, Ir, Cr, BaF, Ba, and/or the like, or a compound or (e.g., any suitable) mixture thereof (e.g., a mixture of Ag and Mg). The cathode electrode CAT may further include a transparent metal oxide layer arranged on the material layer having a small work function.

The anode electrode ANO, the light emitting layer EL and the cathode electrode CAT may form an organic light-emitting element.

A thin-film encapsulation layer 170 including a first inorganic film 172, an organic film 173 and a second inorganic film 193 may be arranged on the cathode electrode CAT. The first inorganic film 171 and the second inorganic film 173 may be in contact with each other at the end of the thin-film encapsulation layer 170. The organic film 172 may be encapsulated by the first inorganic encapsulation film 171 and the second inorganic encapsulation film 173.

Each of the first inorganic film 171 and the second inorganic film 173 may include silicon nitride, silicon oxide, silicon oxynitride, and/or the like. The organic film 172 may include an organic insulating material.

The oxide semiconductor layer 135 described herein may be formed by patterning via a dry etching process. For example, the oxide semiconductor layer 135 may be formed by depositing an oxide semiconductor material layer and then dry etching it using a mask pattern (e.g., a photoresist pattern) as a mask. Typically, CH₄ and/or CF₄ gas may be used as a reactive gas used in the process of etching the oxide semiconductor layer 135. However, forming a precise pattern with these reactive gases due to their low etch selectivity and/or low etch rate with the oxide semiconductor layer 135, such as IGZO. This imprecision in the pattern shape of the oxide semiconductor layer 135 negative impacts (has a negative effect on) the electrical characteristics when driving the transistor, thereby deteriorating the display quality of the display device 1. The term “etch selectivity” as used herein is an amount etching that occurs to IGZO or a compound thereof compared (e.g., relative) to a total amount of etching that occurs an oxide semiconductor layer that includes the IGZO or a compound thereof.

Hereinafter, a method of fabricating a transistor array substrate and a display device that may precisely etch an oxide semiconductor layer, especially an oxide semiconductor layer made of IGZO will be described.

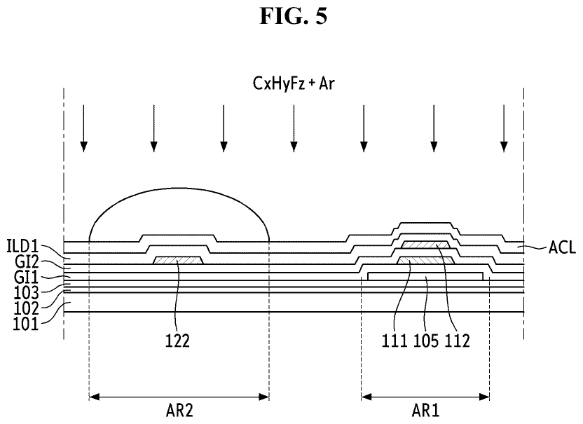

FIGS. 5 to 8 are cross-sectional views showing processing steps of a method of fabricating a transistor array substrate according to one or more embodiments of the present disclosure. FIGS. 5 to 8 show processes for forming from the substrate 101 to the second via layer VIA2 of FIG. 4.

First, referring to FIG. 5, a substrate 101 is prepared, on which a silicon transistor region AR1 and an oxide transistor region AR2 are defined.

Subsequently, a barrier layer 102 and a buffer layer 103 are sequentially stacked on the substrate 101 to form a silicon semiconductor layer 105. The silicon semiconductor layer 105 may be formed by forming a material layer for a silicon semiconductor layer on the buffer layer 103 and then patterning it via a photolithography process.

Subsequently, a first gate insulator GI1 is formed entirely on the buffer layer 103 on which the silicon semiconductor layer 105 is formed. A first gate electrode 111 is formed on the first gate insulator GI1. The first gate electrode 111 may be formed by entirely depositing a material layer for a first conductive layer on the first gate insulator GI1 and then patterning it via a photolithography process.

Subsequently, a second gate insulator GI2 is formed entirely on the first gate insulator GI1 on which the first gate electrode 111 is formed. A second electrode 121 of a capacitor Cst is formed on the second gate insulator GI2. The second electrode 121 of the capacitor Cst may be formed by depositing a material layer for a second conductive layer entirely and then patterning it via a photolithography process. Then, a first interlayer dielectric film ILD1 is formed entirely on the second gate insulator GI2 on which the second electrode 121 of the capacitor Cst is formed.

Subsequently, a material layer ACL for an oxide semiconductor layer to form an oxide semiconductor layer is deposited entirely on the first interlayer dielectric layer ILD1. Subsequently, a photoresist pattern PRP is formed on the material layer ACL for the oxide semiconductor layer where the oxide semiconductor layer is to be formed via a photolithography process. The photoresist pattern PRP may work as a mask in the etching process of the material layer ACL for the oxide semiconductor layer.

Subsequently, the material layer ACL for the oxide semiconductor layer is etched (e.g., dry-etched). The dry etching process may be performed using ICP (inductively coupled plasma) equipment. Dry etching process conditions may include an etching gas, an etching gas ratio, a source power, a bias voltage, and a pressure.

The etching gas may include a fluorinated hydrocarbon (CxHyFz) gas. By using a fluorinated hydrocarbon (CxHyFz) gas as the etching gas for IGZO, it is possible to etch IGZO into a desired or suitable shape because it exhibits high etch selectivity and high etch rate, as shown in the Examples described in more detail elsewhere herein. According to one or more embodiments, the contents (e.g., amounts, (e.g., stoichiometry)) of carbon, hydrogen and fluorine in the fluorinated hydrocarbon (CxHyFz) gas may be adjusted. For example, the content (e.g., amount) of carbon (i.e., x) may be an integer between 1 and 10, the content (e.g., amount) of hydrogen (i.e., y) may be an integer between 1 and 10, and the content (e.g., amount) of fluorine (i.e.,, z) may be an integer between 1 and 10. According to one or more embodiments of the present disclosure, the fluorinated hydrocarbon (CxHyFz) gas may be C₃H₂F₆, C₃H₄F₄, and/or C₃H₆F₄. In one or more embodiments, the content (e.g., amount) of hydrogen may be greater than the content (e.g., amount) of fluorine (for example, y may be greater than z) because it exhibits high etch selectivity and high etch rate.

The etching gas may further include argon (Ar) gas along with the fluorinated hydrocarbon (CxHyFz) gas. In this instance, the proportion (e.g., amount) of the argon (Ar) gas may be greater than the proportion (e.g., amount) of the fluorinated hydrocarbon (CxHyFz) gas. For example, the proportion (e.g., amount) of the argon (Ar) gas to a total sum of the fluorinated hydrocarbon (CxHyFz) gas and the argon (Ar) gas may range from 60% to 99%. The proportion (e.g., amount) of the fluorinated hydrocarbon (CxHyFz) gas may range from 1% to 40%. For example, an amount of the argon gas may be from 60% to 99% and an amount of the fluorinated hydrocarbon gas may be from 1% to 40% based on a total sum amount of 100% for the combined gas (e.g., the fluorinated hydrocarbon gas and the argon gas). In some embodiments, the etching gas may further include gases such as xenon (Xe), krypton (Kr), nitrogen (N2), helium (He), and a (e.g., any suitable) combination thereof.

The source power may be equal to or greater than 1,000 watt (W). For example, the source power may be (e.g., range) from 1,000 W to 5,000 W. In the ICP equipment for etching the oxide semiconductor layer, atoms or molecules may be dissociated using the source power in the described range. The bias voltage may be −150 volt (V) or higher. For example, the bias voltage may be (e.g., range) from −150 V to −500 V. Because a suitable (e.g., certain) amount of ion energy is desired or required to etch the oxide semiconductor layer, the bias voltage may be used in the described range. In this instance, a ratio of the source power to the bias voltage may be equal to or greater than 8, for example, 8 to 30. By adjusting the ratio of the source power to the bias voltage in the described range, it may be possible to easily etch the oxide semiconductor layer. The process pressure may be equal to or less than 10millitorr (mTorr). For example, the process pressure may be (e.g., range) from 1 mTorr to 10 mTorr. For anisotropic etching of the oxide semiconductor layer, it may be desirable that the process pressure is equal to or less than 10 mTorr.

In some embodiments, the temperature range of the substrate 101 may be adjusted. The temperature range of the substrate 101 may be adjusted by a temperature control member (e.g., cooling plate, and/or the like) provided in the ICP equipment, and the temperature of the substrate 101 may be adjusted to be (e.g., in the range of) 10° C. to 100° C. By adjusting the temperature of the substrate 101 in the described range, it may be possible to prevent or reduce the photoresist pattern from burning, and the oxide semiconductor layer may be easily etched.

By etching the oxide semiconductor layer of IGZO under the herein-described process conditions, an etch selectivity of (e.g., at least) 1.5 or more and an etch rate of (e.g., at least) 30 nanometer per minute (nm/min) or more may be achieved, as in the Examples described in more detail elsewhere herein. For example, the etch selectivity of IGZO to the oxide semiconductor layer may be (e.g., range) from 1.5 to 3, and the etch rate may be (e.g., range) from 30 nm/min to 60 nm/min. According to this embodiment, in an etching process for forming the oxide semiconductor layer, for example, an IGZO pattern, a high etch selectivity and a high etch rate may be achieved by using the fluorinated hydrocarbon (CxHyFz) gas as an etching gas.

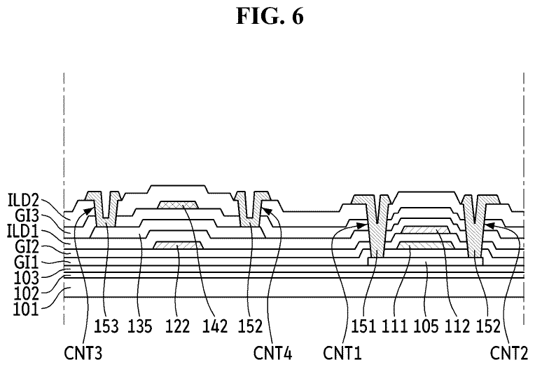

An oxide semiconductor layer 135 (see FIG. 6) may be formed by etching the material layer ACL for the oxide semiconductor layer under the herein-described process conditions.

Subsequently, referring to FIG. 6, a third gate insulator GI3 is formed entirely on the first interlayer dielectric film ILD1 on which the oxide semiconductor layer 135 is formed. A second gate electrode 142 is formed on the third gate insulator GI3. The second gate electrode 142 may be formed by depositing a material layer for a third conductive layer entirely and then patterning it via a photolithography process. Subsequently, a second interlayer dielectric film ILD2 is formed entirely on the third gate insulator GI3 on which the second gate electrode 142 is formed.

Subsequently, by etching the first gate insulator GI1, the second gate insulator GI2, the first interlayer dielectric film ILD1, the third gate insulator GI3 and the second interlayer dielectric film ILD2, contact holes CNT3 and CNT4 exposing the oxide semiconductor layer 135 and contact holes CNT1 and CNT2 exposing the silicon semiconductor layer 105 are formed.

Subsequently, a patterned fourth conductive layer 150 is formed on the second interlayer dielectric film ILD2. The fourth conductive layer 150 may include a first source electrode 151 and a first drain electrode 152 of the transistor arranged in the silicon semiconductor region AR1, and a first source electrode 153 and a first drain electrode 154 of the transistor arranged in the oxide semiconductor region AR2.

The patterned fourth conductive layer 150 may be formed by patterning via a photolithography process. For example, by depositing the material layer for the fourth conductive layer entirely on the second interlayer dielectric film ILD2, it may be deposited (e.g., even) into the contact holes CNT1, CNT2, CNT3 and CNT4. Accordingly, the first source electrode 151 and the first drain electrode 152 of the transistor arranged in the silicon semiconductor region AR1, and the first source electrode 153 and the first drain electrode 154 of the transistor arranged in the oxide semiconductor region AR2 may be electrically connected to the silicon semiconductor layer 105 and the oxide semiconductor layer 135.

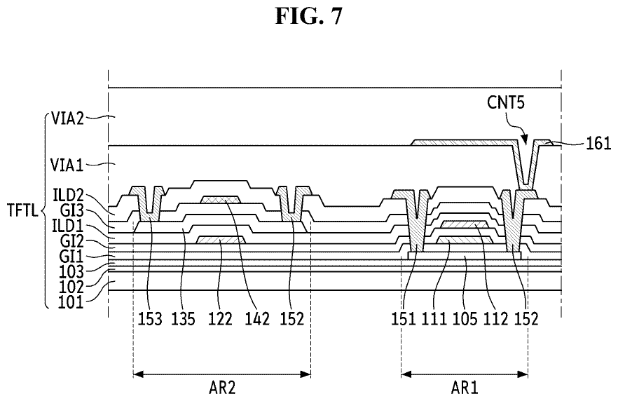

Subsequently, referring to FIG. 7, an inorganic or organic insulating material is formed over the substrate 101 on which the fourth conductive layer 150 is formed, so that a first via layer VIA1 is formed. The first via layer VIA1 may provide a flat surface over the underlying transistors having different heights. Subsequently, the first via layer VIA1 is patterned via a photolithography process, so that a contact hole CNT5 exposing the first drain electrode 152 of the transistor arranged in the silicon semiconductor area AR1 is formed.

Subsequently, an anode connection electrode 161 is formed on the first via layer VIA1. The anode connection electrode 161 may be formed by entirely depositing a material layer for a fifth conductive layer on the first via layer VIA1 and then patterning it via a photolithography process. The anode connection electrode 161 may be connected to the first drain electrode 152 of the transistor arranged in the silicon semiconductor area AR1 through the contact hole CNT5. Subsequently, a second via layer VIA2 is formed on the first via layer VIA1 on which the anode connection electrode 161 is formed, so that a transistor array substrate TFTL is formed.

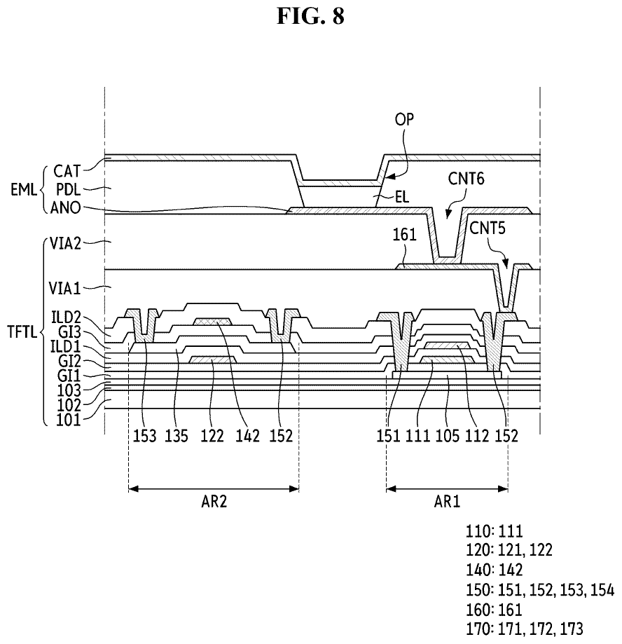

Subsequently, referring to FIG. 8, by patterning the second via layer VIA2 via a photolithography process, a contact hole CNT6 exposing the anode connection electrode 161 is formed. Subsequently, an anode electrode ANO is formed on the second via layer VIA2. The anode electrode ANO may be formed by entirely depositing a material layer for an anode electrode on the second via layer VIA2 and then patterning it via a photolithography process. The anode electrode ANO may be connected to the anode connection electrode 161 via the contact hole CNT5. Subsequently, a pixel-defining layer PDL is formed on the second via layer VIA2 on which the anode electrode ANO is formed. The pixel-defining layer PDL may be formed by applying an organic or inorganic material. Subsequently, the pixel-defining layer PDL is patterned via a photolithography process to form an opening OP exposing the anode electrode ANO. The opening OP may define an area where a light emitting layer is to be formed and may partition an emission area where light substantially exits.

Subsequently, a light emitting layer EL is formed on the anode electrode ANO. The light emitting layer EL may be formed by depositing or printing an organic material layer. Subsequently, an emission device layer EML may be formed by forming a cathode electrode CAT on the pixel-defining layer PDL and the light emitting layer EL. Accordingly, a display device including the transistor array substrate TFTL and the emission device layer EML may be fabricated.

As described herein, according to one or more embodiments of the present disclosure, in an etching process for forming the oxide semiconductor layer, for example, an IGZO pattern, a high etch selectivity and a high etch rate may be achieved by using fluorinated hydrocarbon (CxHyFz) gas as the etching gas. As a result, by precisely forming the oxide semiconductor layer, the electrical characteristics of the transistor may be improved, and the display quality of the display device may be improved.

In other words, the method for fabricating a transistor array substrate and a display device involves preparing a substrate and forming various layers, including silicon and IGZO oxide semiconductor layers, which are patterned and etched using photolithography and ICP equipment. The use of fluorinated hydrocarbon gas (CxHyFz), such as C₃H₂F₆, C₃H₄F₄, or C₃H₆F₄, is crucial for achieving high etch selectivity and rate, essential for precise formation of the IGZO layer. The contents of carbon, hydrogen, and fluorine in the gas can be adjusted, with a higher hydrogen content than fluorine being preferable for better etch selectivity and rate.

Subsequent steps (e.g., acts or tasks) include forming gate insulators, electrodes, and interlayer dielectric films, followed by the deposition and patterning of conductive layers to create source and drain electrodes. Additional layers, such as via layers and pixel-defining layers, are formed to provide a flat surface and define the emission area for the light-emitting layer. Finally, the light-emitting layer and emission device layer are formed, completing the display device. This precise etching process enhances the electrical characteristics of the transistors and improves overall display quality.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display device may be formed on one integrated circuit (IC) chip or on separate IC chips. Further, the one or more suitable components of the display device may be implemented on a flexible printed circuit film, a tape carrier package (TCP), a printed circuit board (PCB), or formed on one substrate. Further, the one or more suitable components of the display device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

Hereinafter, examples of the etching process of the herein-described oxide semiconductor layer will be disclosed.

### EXAMPLES

### Example 1

A silicon oxide layer (SiOx) was formed on a glass substrate, and an IGZO layer was stacked on the silicon oxide layer. After forming a photoresist pattern on the IGZO layer, the IGZO layer was etched. In doing so, CH₄ and CF₄ each were mixed with Ar gas separately as the etching gases.

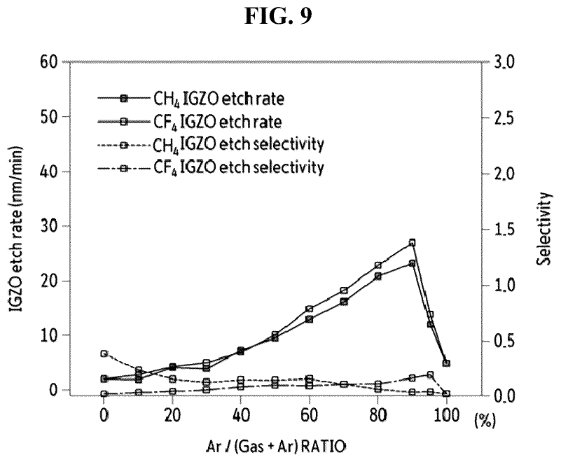

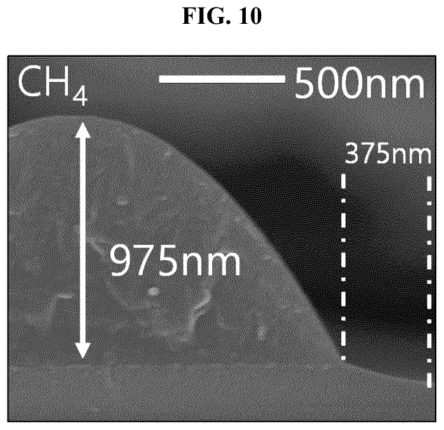

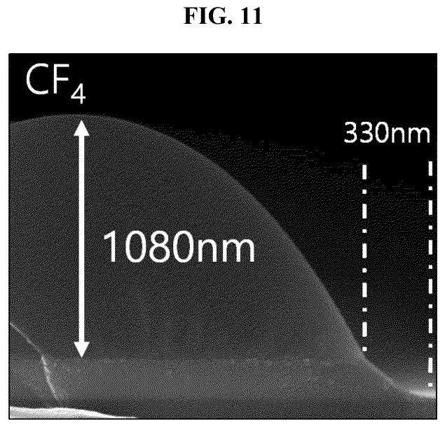

In the etching gases (Ar+CH₄ and Ar+CF₄), the etch selectivity and etch rate of the IGZO layer according to the ratio of Ar gas were measured and are shown in FIG. 9. SEM images of a substrate according to an example containing Ar and CH₄ gas and a substrate according to an example containing Ar and CF₄ gas are shown in FIGS. 10 and 11, respectively.

FIG. 9 is a graph showing the etch selectivity and the etch rate of the IGZO layer according to Example 1. FIG. 10 is an SEM image of a substrate etched using Ar gas and CH₄ gas according to Example 1. FIG. 11 is an SEM image of a substrate etched using Ar gas and CF₄ gas according to Example 1.

Referring to FIG. 9, in both the example using Ar gas and CH₄ gas and the example using Ar gas and CF₄ gas as etching gases, etch selectivity was less than 0.5 and etch rate was less than 30 nanometer per minute (nm/min). In the example shown in FIG. 10 where Ar gas and CH₄ gas were used as the etching gas, the length of a side of the IGZO layer remaining outside the photoresist pattern was 375 nanometer (nm). In the example shown in FIG. 11 where Ar gas and CF₄ gas were used as the etching gas, the length of a side of the IGZO layer remaining outside the photoresist pattern was 330 nm.

In view of the preceding, it may be seen that the etching gas containing CF₄ or CH₄ gas is not suitable for etching the IGZO layer to form a pattern.

### Example 2

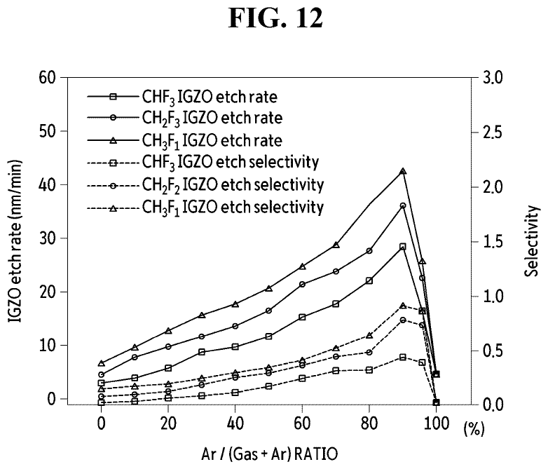

Under the same conditions as in Example 1, the IGZO layer was etched by mixing one of C₃H₂F₆, C₃H₄F₄ or C₃H₆F₂ gas with Ar gas, i.e., separately, as etching gases. The etch selectivity and etch rate of the IGZO layer according to the ratio of Ar gas to the total etching gas (Ar+CHF₃, Ar+CH₂F₂ or Ar+CH₃F₁) were measured, and are shown in FIG. 12.

FIG. 12 is a graph showing the etch selectivity and the etch rate of the IGZO layer according to Example 2.

Referring to FIG. 12, the example using Ar gas and CHF₃ gas as the etching gas exhibited an etch selectivity of less than 0.5 and an etch rate of less than 45 nm/min, and the example using Ar gas and CH₂F₂ gas exhibited an etch selectivity of less than 0.8 and an etch rate of less than 45 nm/min. The example using Ar gas and CH₃F₁ gas exhibited an etch selectivity of less than 1.0 and an etch rate of less than 45 nm/min.

In view of the preceding, it may be seen that the etch selectivity and the etch rate for IGZO were increased by using the gas in which hydrogen and fluorine are mixed compared to Example 1 in which the gas mixed with only hydrogen or fluorine was used.

### Example 3

Under the same conditions as in Example 1, the IGZO layer was etched by mixing one of C₃H₂F₆, C₃H₄F₄ or C₃H₆F₂ gas with Ar gas, i.e., separately, as etching gases. The source power of the ICP equipment was 2,000 watt (W), the bias voltage was −200 volt (V), and the pressure was 2 millitorr (mTorr).

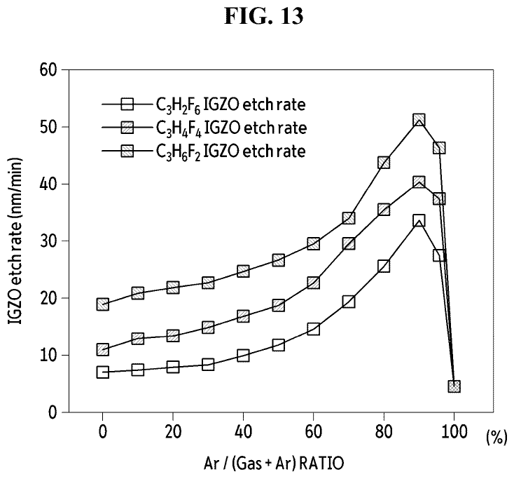

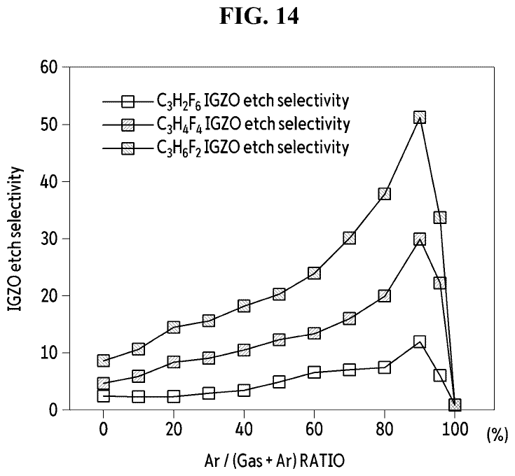

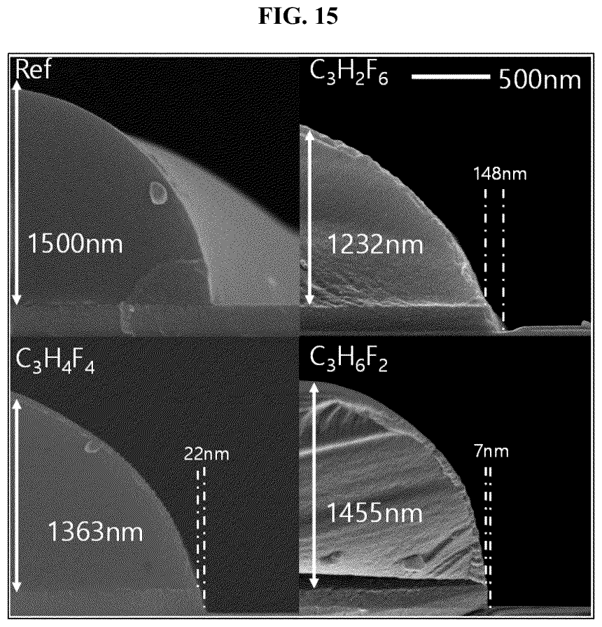

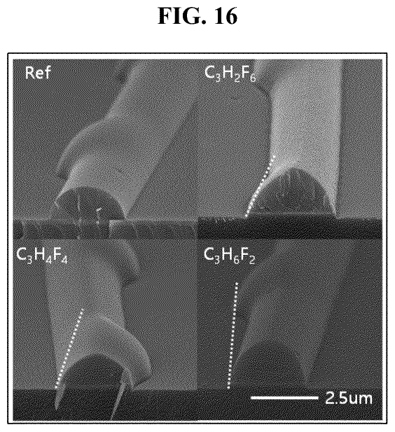

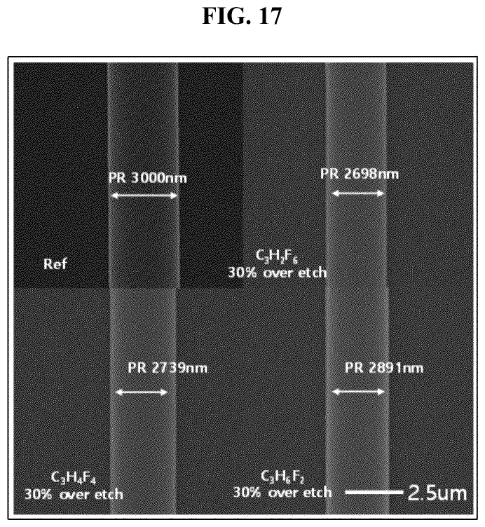

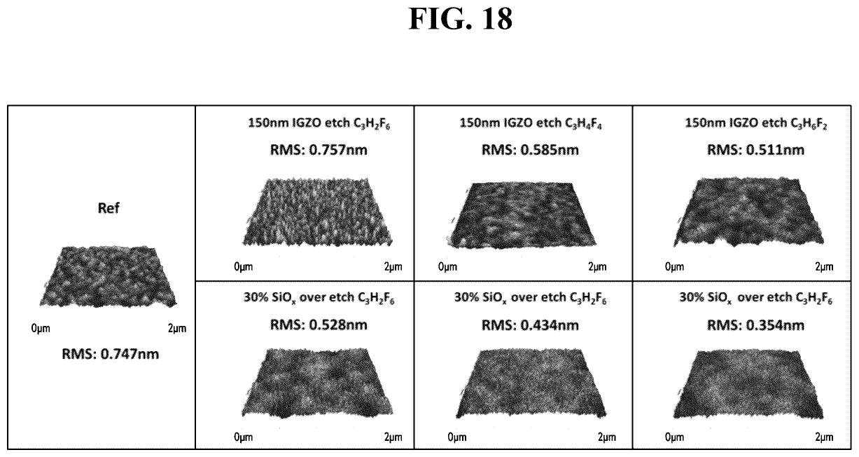

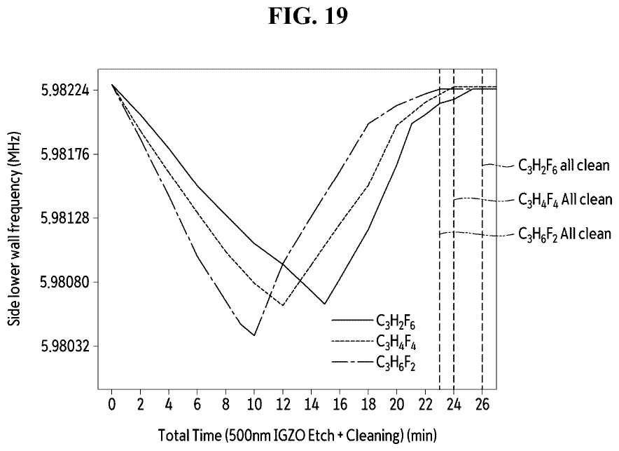

The etch rate of the IGZO layer according to the ratio of Ar gas to the total etching gas (Ar+C₃H₂F₆, Ar+C₃H₄F₄ or Ar+C₃H₆F₂) was measured and is shown in FIG. 13, and the etch selectivity is shown in FIG. 14. SEM images of cross-sections of substrates are shown in FIG. 15, and SEM images of the other cross-sections of the substrate are shown in FIG. 16. SEM images of the substrates when viewed from the top after the IGZO layer was overly etched by 30% (e.g., etched 30% more than required) using the etching gases described in Example 3 are shown in FIG. 17. Images obtained by measuring the surface roughness of the etched areas when the thickness of the IGZO layer were etched only by 150 nm and when they were overly etched by 30% using the etching gases described in Example 3 are shown in FIG. 18. In Example 3, the process of etching the IGZO layer by approximately 500 nm and then cleaning it (H₂/Ar gas ratio of 1:1) was measured in real time using a quartz crystal microbalance (QCM) equipment, and the results are shown in FIG. 19.

FIG. 13 is a graph showing the etch rate of the IGZO layer according to Example 3. FIG. 14 is a graph showing the etch selectivity of the IGZO layer according to Example 3. FIG. 15 is SEM images of a cross-section of the substrate according to Example 3. FIG. 16 is SEM images of another cross-section of the substrate according to Example 3. FIG. 17 is SEM images of the substrate according to Example 3 when viewed from the top. FIG. 18 shows images in which the surface roughness of each of the IGZO layer and silicon oxide according to Example 3 are measured. FIG. 19 is a graph showing results measured by the QCM equipment during the process of cleaning after etching the IGZO layer according to Example 3.

In FIGS. 15 to 18, a comparative example (i.e., “Ref”) shows results of Example 1 using the CH₄ gas. In FIG. 18, when the IGZO layer is etched by only 150 nm, the IGZO layer remains, and thus the surface roughness of the IGZO layer is shown. When the IGZO layer is overly etched by 30%, the IGZO layer is removed entirely, and thus the surface roughness of the underlying silicon oxide film is shown. The surface roughness in FIG. 18 was measured using an atomic force microscope (AFM). In the graph of FIG. 19, the x-axis represents total time, and the y-axis represents frequency. The frequency decreases as contamination increases.

Referring to FIGS. 13 and 14, an etch selectivity of 0.5 or more and an etch rate of 30 or more were obtained in each (e.g., all) of the example using Ar gas and C₃H₂F₆ gas, the example using Ar gas and C₃H₄F₄ gas, and the example using Ar gas and C₃H₆F₂ gas as the etching gas. In particular, the etch rate and etch selectivity increased as the content (e.g., amount) of H increased and the content (e.g., amount) of F decreased, and the etch rate and etch selectivity increased as the content (e.g., amount) of H is greater than the content (e.g., amount) of F.

Referring to FIG. 15, the lengths of sides of the IGZO layers remaining outside the photoresist pattern were 148 nm, 22 nm, and 7 nm. It may be seen that the lengths of the sides decreased significantly as the content (e.g., amount) of H increased and the content (e.g., amount) of F decreased in the etching gas.

It may be seen from FIGS. 16 and 17 that the slope of the photoresist pattern after the etching process increased as the content (e.g., amount) of H increased and the content (e.g., amount) of F decreased in the etching gas. In some embodiments, the width of the photoresist pattern increased as the content (e.g., amount) of H increased and the content (e.g., amount) of F decreased.

In some embodiments, referring to FIG. 18, when the IGZO layer was etched by only 150 nm, the surface roughness of each of the IGZO layers were 0.757 nm, 0585 nm and 0.511 nm, which decreased as the content (e.g., amount) of H increased and the content (e.g., amount) of F decreased in the etching gas. When the IGZO layer was overly etched by 30%, the surface roughness of each of the silicon oxide films were 0.528 nm, 0.434 nm and 0.354 nm, which decreased as the content (e.g., amount) of H increased and the content (e.g., amount) of F decreased in the etching gas. In view of the preceding, it may be seen that C₃H₆F₂ gas has a higher content (e.g., amount) of H and a lower content (e.g., amount) of F than the other gases, and thus it may reduce damage to the underlying layers.

In some embodiments, referring to FIG. 19, the frequency decreased in the initial etching period because contamination increased, while the frequency increased in the cleaning period because contamination decreased. Further, because the etch rate became faster as the content (e.g., amount) of H increased and the content (e.g., amount) of F decreased in the etching gas, it took less time to etch the IGZO layer. In some embodiments, the sum of the etching process time and cleaning time decreased to 26 minutes, 24 minutes and 23 minutes for C₃H₂F₆, C₃H₄F₄, and C₃H₆F₂ gases, respectively.

In view of the preceding, it may be seen that the time desired or required for the entire etching process (including the etching process and the cleaning process) may be reduced as the content (e.g., amount) of H increases and the content (e.g., amount) of F decreases in the etching gas.

The display device according to one or more embodiments of the present disclosure can be applied to various electronic devices. The electronic device according to one or more embodiments of the present disclosure includes the display device described above, and may further include modules or devices having additional functions in addition to the display device.

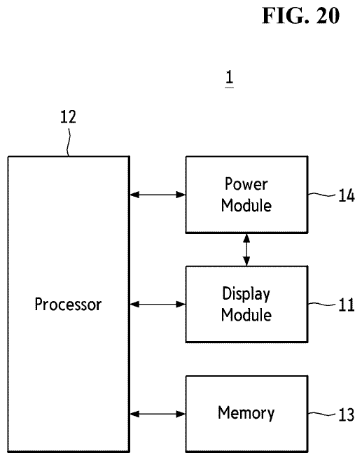

FIG. 20 is a block diagram of an electronic device according to one or more embodiments of the present disclosure.

Referring to FIG. 20, the electronic device 1 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to one or more embodiments of the present disclosure may be included in the display device 10 according to one or more embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

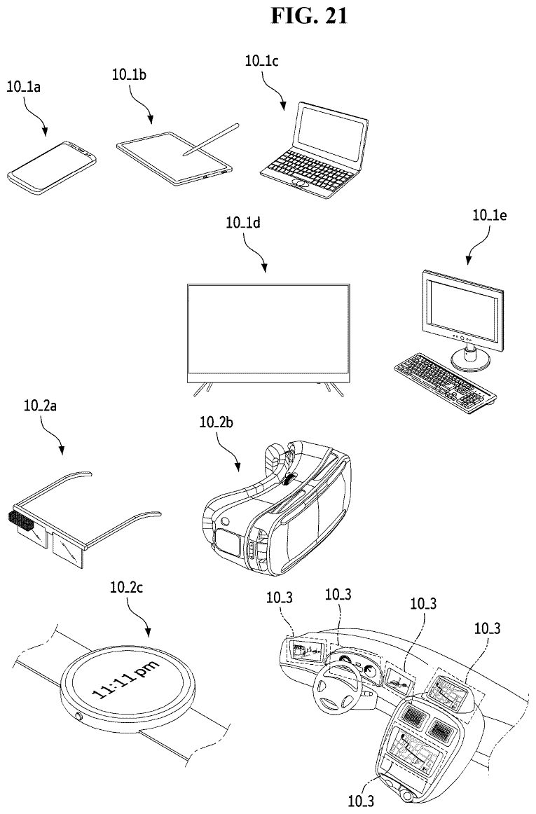

FIG. 21 is a schematic diagram of electronic devices according to one or more embodiments of the present disclosure.

Referring to FIG. 21, various electronic devices to which display devices 10 according to one or more embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

In concluding the detailed description, those skilled in the art will appreciate that many variations and modifications may be made to the embodiments without substantially departing from the principles of the present disclosure. Therefore, the disclosed embodiments of the present disclosure are used in a generic and descriptive sense only and not for purposes of limitation. It will be understood by those of ordinary skill in the art that one or more suitable changes in form and details may be made therein without departing from the spirit and scope as defined by the following claims and equivalents thereof.

What is claimed is:

1. A method comprising:
forming on a substrate, a material layer, the material layer being for an oxide semiconductor layer comprising an indium gallium zinc oxide (IGZO);
forming a photoresist pattern on the material layer; and
etching the material layer using an etching gas comprising a fluorinated hydrocarbon gas represented by CxHyFz, wherein x, y and z are each independently an integer from 1 to 10,
wherein the method is a method of fabricating a transistor array substrate.

2. The method of claim 1, wherein y is greater than z.

3. The method of claim 1, wherein the fluorinated hydrocarbon gas comprises at least one selected from the group consisting of C₃H₂F₆, C₃H₄F₄, and C₃H₆F₂.

4. The method of claim 1, wherein the etching gas further comprises argon gas.

5. The method of claim 4, wherein an amount of the argon gas is from 60% to 99% and an amount of the fluorinated hydrocarbon gas is from 1% to 40% based on a total amount of 100% for the fluorinated hydrocarbon gas and the argon gas.

6. The method of claim 1, wherein the etching of the material layer is carried out with a source power from 1,000 watt (W) to 5,000 W.

7. The method of claim 1, wherein the etching of the material layer is carried out with a bias voltage from −150 volt (V) to −500 V.

8. The method of claim 1, wherein the etching of the material layer is carried out with a ratio of a source power to a bias voltage from 8 to 30.

9. The method of claim 1, wherein the etching of the material layer is carried out with a process pressure from 1 millitorr (mTorr) to 10 mTorr.

10. The method of claim 1, wherein the etching of the material layer is carried out with a temperature of the substrate from 10° C. to 100° C.

11. The method of claim 1, wherein an etch selectivity of the etching gas to the material layer is from 1.5 to 3.

12. The method of claim 1, wherein an etch rate of the material layer is from 30 nanometer per minute (nm/min) to 60 nm/min.

13. The method of claim 1, wherein the etching of the material layer comprises
forming the oxide semiconductor layer and the method further comprises removing the photoresist pattern after the oxide semiconductor layer is formed.

14. The method of claim 13, further comprising:
forming a gate electrode, a source electrode and a drain electrode on the oxide semiconductor layer.

15. A method comprising:
forming on a substrate, a material layer, the material layer being for an oxide semiconductor layer comprising an indium gallium zinc oxide (IGZO);
forming a photoresist pattern on the material layer;
etching the material layer using an etching gas comprising a fluorinated hydrocarbon gas represented by CxHyFz, wherein x, y and z are each independently an integer from 1 to 10;
forming a gate electrode, a source electrode, and a drain electrode on the oxide semiconductor layer; and
forming an emission material layer comprising an anode electrode, a light emitting layer and a cathode electrode on the source electrode and the drain electrode,
wherein the method is a method of fabricating a transistor array substrate.

16. The method of claim 15, wherein the fluorinated hydrocarbon gas comprises at least one selected from the group consisting of C₃H₂F₆, C₃H₄F₄, and C₃H₆F₂.

17. The method of claim 15, wherein the etching gas further comprises argon gas, and
wherein an amount of the argon gas is from 60% to 99% and an amount of the fluorinated hydrocarbon gas is from 1% to 40% based on a total amount of 100% for the fluorinated hydrocarbon gas and the argon gas.

18. The method of claim 15, wherein the etching of the material layer is carried out with a source power from 1,000 W to 5,000 W, a bias voltage from −150 V to −500 V, and a ratio of the source power to the bias voltage from 8 to 30.

19. The method of claim 15, wherein the etching of the material layer is carried out with a process pressure from 1 mTorr to 10 mTorr.

20. The method of claim 15, wherein the etching of the material layer is carried out with a temperature of the substrate from 10° C. to 100° C.

21. An electronic device comprising:
a display device manufactured using a method for manufacturing of a display device and configured to provide an image;
a processor configured to provide an image data signal to the display device;
a memory configured to store a data information for operation; and
a power module configured to generate power,
wherein the method comprising:
forming on a substrate, a material layer, the material layer being for an oxide semiconductor layer comprising an indium gallium zinc oxide (IGZO);
forming a photoresist pattern on the material layer;
etching the material layer using an etching gas comprising a fluorinated hydrocarbon gas represented by CxHyFz, wherein x, y and z are each independently an integer from 1 to 10;
forming a gate electrode, a source electrode, and a drain electrode on the oxide semiconductor layer; and
forming an emission material layer comprising an anode electrode, a light emitting layer and a cathode electrode on the source electrode and the drain electrode,
wherein the method is a method of fabricating a transistor array substrate.
